(19) United States
(12) Patent Application Publication
(10) Pub. No.: US 2026/0043124 A1
(43) Pub. Date: Feb. 12, 2026

(54) FABRICATION OF SCANDIUM-CONTAINING TARGETS

(71) Applicant: SRL Holding Company Pty Ltd, Melbourne (AU)

(72) Inventors: Timothy James Langan, Catonsville, MD (US); Paul George Sanders, Houghton, MI (US)

(21) Appl. No.: 19/295,610

(22) Filed: Aug. 9, 2025

Related U.S. Application Data
(60) Provisional application No. 63/681,659, filed on Aug. 9, 2024.

(51) Int. Cl. C23C 14/34; B22F 10/28; B33Y 10/00; B33Y 70/00; B33Y 80/00; C23C 14/06

(52) U.S. Cl. CPC C23C 14/3414; B22F 10/28; C23C 14/0641; B22F 2201/01; B22F 2201/10; B22F 2201/20; B22F 2301/052; B33Y 10/00; B33Y 70/00; B33Y 80/00

(57) ABSTRACT

Aluminum-scandium sputter targets with controlled compositions and refined microstructures are disclosed. The composition and microstructure of the Al—Sc target may be controlled to deposit AlScN structures with optimal Sc levels. Refining microstructure reduces variations in parameters required for sputter deposition of Al—Sc structures. The fabrication process may utilize a localized heat source such as a laser, electron beam, electric arc, or the like to build the target layer-by-layer from powder feed stock.

### CROSS-REFERENCE TO RELATED APPLICATION

This application claims the benefit of U.S. Provisional Patent Application No. 63/681,659 filed Aug. 9, 2024, which is incorporated herein by reference.

### FIELD OF THE INVENTION

The present invention relates to the fabrication of targets that may be used to produce structures and films containing aluminum and scandium.

### BACKGROUND INFORMATION

The addition of scandium may improve piezoelectric properties of aluminum-nitride films and structures. These structures can be formed by reactive sputter deposition of aluminum and scandium in an environment containing nitrogen. Sputter targets may include separate Sc and Al targets, or combined Sc—Al targets.

Attempts have been made to make aluminum-scandium sputter deposition targets by hot pressing fine pure aluminum and fine pure scandium powder that has been uniformly blended to give a desired bulk composition. In this approach the hot-pressing process is performed above the melting point of aluminum. After pressing, the target blank is cooled. However, coarse discrete second phase particles are formed during this process, resulting in compositional variations with a coarse multiphase microstructure. In another attempted approach, pre-alloyed Al—Sc powder is hot pressed to form a target blank. This approach may reduce compositional variation but melting and slow cooling during hot-pressing still results in the formation of coarse second phase particles. In another attempt to make Al—Sc targets, Sc and Al metals are melted and cast to form an ingot. However, high melting point intermetallic Al—Sc phases form, which make it difficult to cast an ingot with a uniform microstructure. Compositions that have been fabricated using this approach are typically limited to scandium levels of less than 10 weight percent.

Inhomogeneities present in the microstructure of targets are detrimental during deposition of AlSc containing films and structures. These microstructural features can result in reduced performance of AlScN films and structures and can limit process control during the deposition process.

### SUMMARY OF THE INVENTION

The present invention provides aluminum-scandium sputter targets with controlled compositions and refined microstructures. The composition and microstructure of the Al—Sc target may be controlled to deposit AlScN structures with optimal Sc levels. Refining microstructure reduces variations in parameters required for sputter deposition of Al—Sc structures. The fabrication process may utilize a localized heat source such as a laser, electron beam, electric arc, or the like to build the target layer-by-layer from powder feed stock.

An aspect of the present invention is to provide a method of making an aluminum-scandium sputter target comprising depositing a first powder layer comprising Al—Sc particles onto a substrate such as a target backing plate, heating the particles of the first powder layer to form a first Al—Sc alloy layer and rapidly cooling the first Al—Sc alloy layer, depositing at least one additional powder layer comprising Al—Sc particles onto the first Al—Sc alloy layer, and heating the particles of the at least one additional powder layer to form at least one additional Al—Sc alloy layer and rapidly cooling the at least one additional Al—Sc alloy layer.

Another aspect of the present invention is to provide an aluminum-scandium sputter target produced by the method described above.

A further aspect of the present invention is to provide an aluminum-scandium sputter target comprising an Al—Sc alloy comprising a metastable phase that is substantially free of Al₃Sc, Al₂Sc, AlSc and AlSc₂ intermetallics.

Another aspect of the present invention is to provide a method of sputter depositing aluminum scandium nitride on a substrate comprising generating Al—Sc alloy vapor from an Al—Sc alloy target in a nitrogen containing atmosphere to produce AlScN, and depositing the AlScN on a substrate, wherein the Al—Sc alloy target has been produced by the method described above.

A further aspect of the present invention is to provide a method of sputter depositing aluminum scandium nitride on a substrate comprising generating Al—Sc alloy vapor from an Al—Sc alloy target in a nitrogen containing atmosphere to produce AlScN, and depositing the AlScN on a substrate, wherein the Al—Sc alloy comprises a metastable phase that is substantially free of Al₃Sc, Al₂Sc, AlSc and AlSc₂ intermetallics.

These and other aspects of the present invention will be more apparent from the following description.

### BRIEF DESCRIPTION OF THE DRAWINGS

FIG. 1 is a partially schematic top view of a sputter target including an aluminum-scandium alloy provided on a backing plate.

FIG. 2 is a partially schematic side view of the sputter target of FIG. 1.

FIG. 3 is a schematic diagram illustrating a sputter deposition arrangement and method utilizing an Al—Sc sputter target of the present invention.

### DETAILED DESCRIPTION

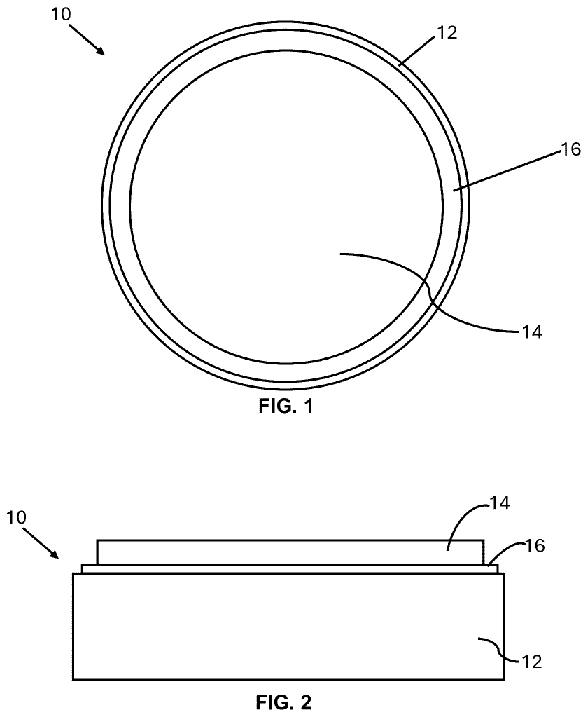

As schematically shown in FIGS. 1 and 2, a sputter target 10 includes a backing plate 12 and an Al—Sc alloy target material 14. At least one bonding layer 16 may optionally be provided between the backing plate 12 and the Al—Sc alloy target 14. The backing plate 12 may be made of any suitable material such as steel, aluminum, copper and the like. As more fully described below, the Al—Sc alloy target 14 may be built up layer-by-layer on the backing plate 12, or alternatively may be built up layer-by-layer on a another substrate to form a free-standing target that is subsequently bonded to a backing plate, e.g., by soldering or brazing with a metal such as iridium. The bonding layer 16 may be made of any suitable material such as metals and metal alloys including indium, steel, iron, aluminum, scandium and the like. The bonding layer 16 may comprise a uniform material through its thickness, or may comprise a graded or non-uniform material. Examples of bonding layers that may be adapted for use with the present Al—Sc alloy target materials are disclosed in U.S. Application Publication No. US 2017/0287685, which is incorporated herein by reference.

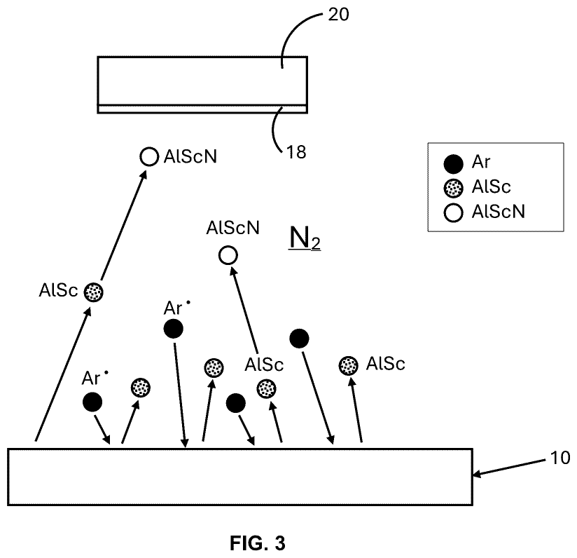

As schematically shown in FIG. 3, a sputter target 10 comprising an Al—Sc alloy target of the present invention may be subjected to ion bombardment by high energy ions, e.g., Ar ions, to dislodge Al—Sc material from the surface of the sputter target 10. A nitrogen atmosphere N₂ is provided, which reacts with the vaporized AlSc to form aluminum scandium nitride. The AlScN material is then deposited on a substrate 20.

The Al—Sc sputter targets produced in accordance with the present invention may be single phase. As used herein, the term “single phase” means a metastable material that may comprise a substantially uniform distribution of Al and Sc atoms thoughout the material. The metastable phase of the Al—Sc alloy may be the predominant phase of the alloy, e.g., may comprise at least 50 volume percent or more of the alloy microstructure up to 95 or 98 or 99 or 100 volume percent. In certain embodiments, the Al—Sc sputter targets may be non-stoichiometric, e.g., may not consist of a particular intermetallic compound of Al₃Sc, Al₂Sc, AlSc or AlSc₂.

The process may utilize a localized heating source to consolidate metal or alloy precursor powders directly into a predefined shape onto a substrate such as a backing plate to form a sputter target. The process may include additive manufacturing techniques, as more fully described below. In addition to advantages associated with refined microstructure, the process can be used to eliminate steps currently required to manufacture sputter targets including pressing, vacuum hot pressing, shaping, bonding and machining.

Scandium has limited solubility in aluminum forming four high melting intermetallic phases (Al₃Sc, Al₂Sc, AlSc, AlSc₂) with stability defined by bulk Sc level in the alloy. A phase diagram for Al—Sc is disclosed in Shevchenko et al, “Thermodynamic Properties of Al—Sc Alloys,” Powder Metallurgy and Metal Ceramics, Vol. 53, Nos. 3-4, July 2014 (Russian Original Vol. 53, Nos. 3-4, March-April 2014), which is incorporated herein by reference.

The targets of the present invention may be formed from Al—Sc powders that are utilized as starting materials for additive manufacturing of the targets. Individual particles of the Al—Sc powders may contain an alloy of Al and Sc in controlled atomic ratios.

Aluminum may be present in the Al—Sc alloys in an amount of at least 40 atomic percent, or at least 50 atomic percent, or at least 55 atomic percent, or at least 60 atomic percent, or at least 65 atomic percent, or at least 70 atomic percent, or at least 75 atomic percent, or at least 80 atomic percent.

Aluminum may be present in the Al—Sc alloys in an amount up to 90 atomic percent, or up to 85 atomic percent, or up to 80 atomic percent, or up to 75 atomic percent, or up to 70 atomic percent, or up to 65 atomic percent, or up to 60 atomic percent, or up to 55 atomic percent, or up to 50 atomic percent.

Aluminum may be present in the Al—Sc alloys in a range of from 40 to 90 atomic percent, or from 50 to 85 atomic percent, or from 55 to 80 atomic percent, or from 60 to 75 atomic percent, or from 65 to 70 atomic percent, or from 70 to 65 atomic percent, or from 75 to 60 atomic percent, or from 80 to 50 atomic percent.

Scandium may be present in the Al—Sc alloys in an amount of at least 10 atomic percent, or at least 15 atomic percent, or at least 20 atomic percent, or at least 25 atomic percent, or at least 30 atomic percent, or at least 35 atomic percent, or at least 40 atomic percent, or at least 42 atomic percent, or at least 45 atomic percent, or at least 50 atomic percent.

Scandium may be present in the Al—Sc alloys in an amount up to 60 atomic percent, or up to 50 atomic percent, or up to 45 atomic percent, or up to 40 atomic percent, or up to 35 atomic percent, or up to 30 atomic percent, or up to 25 atomic percent, or up to 20 atomic percent.

Scandium may be present in the Al—Sc alloys in a range of from 10 to 60 atomic percent, or from 15 to 50 atomic percent, or from 20 to 45 atomic percent, or from 25 to 40 atomic percent, or from 30 to 35 atomic percent, or from 33.3 to 50 atomic percent, or from 35 to 48 atomic percent, or from 40 to 45 atomic percent, or from 42 to 44 atomic percent.

The Al—Sc alloy powders may be produced by a suitable process such as by a direct electrochemical deoxidation reaction, for example, as described in U.S. Pat. No. 7,879,219, which is incorporated herein by reference. An electron deoxidation process may thus be used to produce aluminum-scandium metallic powder directly from Sc-oxide and Al-oxide. The particle size of the Al—Sc alloy powders may be controlled in order to facilitate additive manufacturing. For example, for laser powder bed fusion, the particles may comprise distributions of sizes within specified ranges, such as from 1 to 100 microns, or from 5 to 70 microns, or from 10 to 50 microns. The particle size distributions may be mono-modal, bi-modal or multi-modal. The powders may be milled and sieved to achieve a desired size distribution. Particle morphology may be controlled, for example, by plasma spheroidization techniques known to those skilled in the art. In another approach, the precursor powder can be produced using a rapid solidification process in which aluminum and scandium metal are melted and held at high temperature, e.g., above 1,420° C., under an inert environment for sufficient time to ensure that only a single liquid phase is present. The melt is then solidified directly into granules/particles using a rapid solidification process, e.g., by gas atomization, melt spinning, or the like. In a preferred embodiment, the solidification rate is fast enough to inhibit formation of Al—Sc intermetallic phases. Classification and milling, e.g., using a hammer mill and/or ball mill, of precursor powder may be required to optimize shape and particle size for deposition. Environment may be controlled to limit oxide content in the powder.

The precursor Al—Sc alloy powder may then be printed by additive manufacturing to form the target. The melt rate and cooling rate may be controlled to limit formation of Al—Sc second phases. In one embodiment, the Al—Sc alloy target is built or printed directly onto a backing plate to form a sputter target. In one embodiment, the Al—Sc alloy target is built layer by layer using selective laser or electron beam melting of precursor powder. Another embodiment utilizes laser sintering to fuse the power into the shape of the target. Other embodiments may be based on laser, electron beam, or electric arc assisted deposition of powder, e.g., LENS directed energy deposition system, onto the backing plate. In addition to careful control of cooling/solidification rates, the environment may be carefully controlled to reduce or remove oxygen content in the target material, e.g., by limiting/restricting oxide formation and/or by removing oxygen by reduction using a reactive gas. In one embodiment, the deposition is carried out under reducing conditions.

The additive manufacturing process may include any suitable process such as powder bed fusion, directed energy deposition, binder jetting, and the like. Powder bed fusion is an additive manufacturing process in which thermal energy fuses regions of a powder bed. A thin layer of powder material is spread on a build platform. A heat source, such as a laser, electron beam, and/or the like, may be used to fuse the powder particles together layer-by-layer. After a layer is completed, the build platform may be dropped and another layer of powder material is spread across the printing plate. This process repeats until the part is completed. Directed energy deposition is an additive manufacturing process in which focused thermal energy is used to fuse materials by melting as they are being deposited. As the powder feed material is deposited, the material is melted by a source of focused thermal energy (e.g., an electron beam, a laser, and/or the like). This process continues repeatedly until the layers have solidified. Binder jetting is an additive manufacturing process in which a bonding agent is deposited to join powder materials. The powder material may be spread in a thin layer on a printing plate. Droplets of binder may be deposited into the powder bed to bond the powder at the location of the droplets. After a layer is completed, the printing plate may be dropped and another layer of powder material is spread across the printing plate. This process repeats until the part is completed. The part may undergo post-processing steps such as melting, sintering, infiltration, polishing, plating, or the like.

The steps of heating the Al—Sc alloy particles of the first powder layer and subsequent powder layers may be performed at a heating temperature of at least 1,000° C., or at least 1,200° C., or at least 1,400° C.

The steps of rapidly cooling the first Al—Sc alloy layer and subsequent Al—Sc alloy layers may be performed at a cooling rate of at least 103° C./second, or at least 104° C./second, or at least 105° C./second. The cooling rate may be less than 108° C./second, or less than 107° C./second. For example, the cooling rate may range from 105° C./second to 107° C./second.

The additively manufactured Al—Sc alloy may have a typical thickness of at least 0.5 mm, or at least 1 mm, or at least 2 mm, or at least 2.5 mm, or at least 3 mm. The thickness may be up to 10 mm or more, or up to 8 mm, or up to 6 mm, or up to 5 mm, or up to 4 mm. The thickness may range from 0.5 mm to 10 mm, or from 1 mm to 8 mm, or from 2 mm to 6 mm, or from 2.5 mm to 5 mm or from 3 mm to 4 mm.

The method described herein may be used to recover targets after service by reprinting part or all of an Al—Sc layer. For example, a used target may be removed from the deposition chamber, cleaned and machined if necessary, and placed in the powder bed chamber for rebuilding.

The following examples are intended to illustrate various aspects of the present invention, and are not intended to limit the scope of the invention.

### Example 1

Powder with Al—Sc compositions as listed in Table 1 are produced by electrochemical processing of aluminum oxide and scandium oxide in a fused salt of calcium chloride to directly reduce the mixture of scandium oxide and aluminum oxide into an aluminum-scandium alloy. The direct electrochemical deoxidation reaction is performed in a molten calcium chloride electrolyte at 900° C. to produce high-purity Al—Sc alloys using an electro-deoxidation process as described in U.S. Pat. No. 7,879,219. The individual particles comprise Al and Sc in atomic ratios as listed in Table 1. The particles are crushed by milling, plasma spherodized, and sieved to produce powder having particle sizes within a range of from 10 to 50 microns. The classified precursor powder is deposited onto a pre-machined target backing plate to form a powder layer having a thickness of about 50 microns. A standard laser used in powder bed fusion additive manufacturing processes is used to heat the powder layer to a temperature of about 1,400° C., followed by rapid solidification of the fused layer at a cooling rate of at least 105° C./second from the peak temperature. The rapid cooling rate results from the target backing plate acting as a rapid heat sink after the laser beam has passed over an area of the Al—Sc alloy powder. The target structure is built up on the backing plate in a layer-by-layer fashion using selective laser melting to a total thickness of about 3 mm. The rapid solidification rate in the deposited target forms a single phase Al—Sc alloy material. The environment in the SLM chamber is controlled to reduce oxidation during deposition.

TABLE 1
Al-Sc Compositions (Atomic %)

| Composition No. | Sc | Al |
|---|---|---|
| 1 | 10 | 90 |
| 2 | 15 | 85 |
| 3 | 20 | 80 |
| 4 | 23 | 77 |
| 5 | 25* | 75 |
| 6 | 27 | 73 |
| 7 | 30 | 70 |
| 8 | 32 | 68 |
| 9 | 33.3** | 66.7 |
| 10 | 35 | 65 |
| 11 | 40 | 60 |
| 12 | 42 | 58 |
| 13 | 43 | 57 |
| 14 | 44 | 56 |
| 15 | 45 | 55 |
| 16 | 48 | 52 |
| 17 | 50*** | 50 |
| 18 | 52 | 48 |
| 19 | 55 | 45 |
| 20 | 60 | 40 |

*Al₃Sc Intermetallic
**Al₂Sc Intermetallic
***AlSc Intermetallic

### Example 2

Al—Sc powders compositions as listed in Table 1 are produced by vacuum gas atomization. The classified and milled precursor powder is deposited onto a pre-machined target backing plate. The target structure is built up in a layer-by-layer fashion using selective laser melting. Solidification rate in the deposited target is controlled to reduce or eliminate formation of second phase AlSc intermetallics. The environment in the SLM chamber is controlled to reduce oxidation during deposition.

### Example 3

Blended pure Al and pure Sc powder with bulk compositions as listed in Table 1 are deposited onto a pre-machined target backing plate. The target structure is built up in a layer-by-layer fashion using selective laser melting. Solidification rate in the deposited target is optimized to reduce or eliminate formation of second phase AlSc intermetallics. The environment in the SLM chamber is controlled to reduce oxidation during deposition.

### Example 4

Used targets may be recycled by reprinting with Al—Sc. An AlSc alloy target at the end serviceable life for deposition is machined and placed into the powder deposition chamber. Al—Sc powders with compositions as listed in Table 1 are classified, milled and deposited onto a pre-machined target. The new target structure is built up in a layer-by-layer fashion using selective laser melting. Solidification rate in the deposited target is controlled to reduce or eliminate formation of second phase AlSc intermetallics. The environment in the SLM chamber is controlled to reduce oxidation during deposition.

As used herein the terms “including,” “containing” and like terms are understood to be synonymous with “comprising” and are therefore open-ended and do not exclude the presence of additional undescribed or unrecited elements, materials, ingredients or method steps. As used herein the term “consisting essentially of” is understood to include the specified elements, materials, ingredients or method steps and those that do not materially affect basic and novel characteristic(s). As used herein the term “consisting of” is understood to exclude the presence of any unspecified element, material, ingredient or method step.

As used herein the term “substantially free” refers to a particular element or material that is not purposefully added to a composition and is present only as an impurity or in a trace amount.

It should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

In this application, the use of the singular includes the plural and plural encompasses singular, unless specifically stated otherwise. In addition, in this application, the use of “or” means “and/or” unless specifically stated otherwise, even though “and/or” may be explicitly used in certain instances. In this application and the appended claims, the articles “a,” “an,” and “the” include plural referents unless expressly and unequivocally limited to one referent.

Whereas particular embodiments of this invention have been described above for purposes of illustration, it will be evident to those skilled in the art that numerous variations of the details of the present invention may be made without departing from the invention as defined in the appended claims.

What is claimed is:

1. A method of making an aluminum-scandium sputter target comprising:
depositing a first powder layer comprising Al—Sc particles onto a substrate;
heating the particles of the first powder layer to form a first Al—Sc alloy layer and rapidly cooling the first Al—Sc alloy layer;
depositing at least one additional powder layer comprising Al—Sc particles onto the first Al—Sc alloy layer; and
heating the particles of the at least one additional powder layer to form at least one additional Al—Sc alloy layer and rapidly cooling the at least one additional Al—Sc alloy layer.

2. The method of claim 1, wherein the steps of heating the particles of the first powder layer and heating the particles of the at least one additional powder layer are performed at a heating temperature of at least 1,400° C.

3. The method of claim 1, wherein the steps of heating the particles of the first powder layer and heating the particles of the at least one additional powder layer are performed with a laser, e-beam or electric arc.

4. The method of claim 1, wherein the steps of rapidly cooling the first Al—Sc alloy layer and rapidly cooling the at least one additional Al—Sc alloy layer are performed at a cooling rate of at least 103° C./second.

5. The method of claim 4, wherein the cooling rate is from 105° C./second to 107° C./second.

6. The method of claim 1, wherein the method comprises a powder bed fusion additive manufacturing process.

7. The method of claim 1, wherein the method is performed in an atmosphere comprising a vacuum, inert gas, or a reducing gas that reacts with oxygen.

8. The method of claim 1, wherein the substrate comprises a target backing plate.

9. The method of claim 8, wherein the first powder layer is deposited directly on the target backing plate.

10. The method of claim 8, wherein the first powder layer is deposited on an intermediate bonding layer at least partially covering the target backing plate.

11. The method of claim 10, wherein the bonding layer is uniform through a thickness of the bonding layer.

12. The method of claim 10, wherein the bonding layer is non-uniform through a thickness of the bonding layer.

13. The method of claim 12, wherein the non-uniform bonding layer is graded through the thickness of the bonding layer.

14. The method of claim 10, wherein the bonding layer is additively manufactured on the target backing plate.

15. The method of claim 1, wherein the Al—Sc particles have particle sizes of from 10 to 50 microns.

16. The method of claim 1, wherein the Al—Sc alloy layers comprise a single phase.

17. The method of claim 1, wherein the Al—Sc alloy layers comprise a metastable phase that is substantially free of Al₃Sc, Al₂Sc, AlSc and AlSc₂ intermetallics.

18. The method of claim 1, wherein the Al—Sc alloy layers comprise from 40 to 90 atomic percent Al and from 10 to 60 atomic percent Sc.

19. The method of claim 1, wherein the Al—Sc alloy layers comprise from 50 to 80 atomic percent Al and from 20 to 50 atomic percent Sc.

20. An aluminum-scandium sputter target produced by the method of claim 1.

21. An aluminum-scandium sputter target comprising an Al—Sc alloy comprising a metastable phase that is substantially free of Al₃Sc, Al₂Sc, AlSc and AlSc₂ intermetallics.

22. A method of sputter depositing aluminum scandium nitride on a substrate comprising generating Al—Sc alloy vapor from an Al—Sc alloy target in a nitrogen containing atmosphere to produce AlScN, and depositing the AlScN on a substrate, wherein the Al—Sc alloy target has been produced by the method of claim 1.

23. A method of sputter depositing aluminum scandium nitride on a substrate comprising generating Al—Sc alloy vapor from an Al—Sc alloy target in a nitrogen containing atmosphere to produce AlScN, and depositing the AlScN on a substrate, wherein the Al—Sc alloy comprises a metastable phase that is substantially free of Al₃Sc, Al₂Sc, AlSc and AlSc₂ intermetallics.
